(19) United States
(12) Patent Application Publication
(10) Pub. No.: US 2017/0264282 A1
(43) Pub. Date: Sep. 14, 2017

(54) SWITCHING CIRCUIT

(71) Applicant: TOYOTA JIDOSHA KABUSHIKI KAISHA, Toyota-shi, Aichi-ken (JP)

(72) Inventors: Masahiro SUGIMOTO, Toyota-shi (JP); Yukihiko WATANABE, Nagakute-shi (JP); Kensaku YAMAMOTO, Okazaki-shi (JP)

(73) Assignee: TOYOTA JIDOSHA KABUSHIKI KAISHA, Toyota-shi, Aichi-ken (JP)

(21) Appl. No.: 15/508,219

(22) PCT Filed: Aug. 21, 2015
(86) PCT No.: PCT/JP2015/004224

§ 371 Date: Mar. 2, 2017

(30) Foreign Application Priority Data
Oct. 10, 2014 (JP) 2014-209138

(51) Int. Cl. H03K 17/0812; H01L 27/02; H01L 27/06; H01L 29/16; H01L 29/78

(52) U.S. Cl. CPC H03K 17/08122; H01L 29/1608; H01L 29/78; H01L 27/0629; H01L 29/16; H01L 27/0285

(57) ABSTRACT

A switching circuit disclosed, herein, includes a main MOSFET 12, a control MOSFET 14, and a diode 16. The main MOSFET is formed in a SiC semiconductor layer. A channel type of the main MOSFET is a first conductivity type. A channel type of the control MOSFET is a second conductivity type. A source of the control MOSFET is connected to-a gate of the main MOS-FET. A cathode of the diode is connected to a gate of one of the main MOSFET and the control MOSFET. An anode of the diode is connected to a gate of the other of the main MOSFET and the control MOSFET. A channel type of the one is an n-type. A channel type of the other is a p-type.

### TECHNICAL FIELD

### CROSS-REFERENCE TO RELATED APPLICATION

This application claims priority to Japanese Patent Application No. 2014-209138 filed on Oct. 10, 2014, the contents of which are hereby incorporated by reference into the present application.

A technology disclosed herein relates to a switching circuit.

### BACKGROUND ART

Japanese Patent Application Publication No. 2012-54378 discloses a MOSFET. Further, in recent years, SiC has been used as a semiconductor material for a MOSFET in some cases.

### SUMMARY OF INVENTION

It has been known that in a MOSFET formed in a SiC semiconductor layer, an application of an inappropriate potential to a gate of the MOSFET changes a gate threshold value. For example, in a MOSFET of an n-channel type, the application of a negative potential that is lower than a predetermined value to a gate of the MOSFET changes the gate threshold value toward a negative side. Alternatively, in a MOSFET of a p-channel type, the application of a positive potential that is higher than a predetermined value to a gate of the MOSFET changes the gate threshold value toward a positive side. In a MOSFET formed in a SiC semiconductor layer, a possible reason for such a change in gate threshold value is that since the trap density at the interface between a gate insulator film and the SiC semiconductor layer is high, a large number of carriers is captured in the interface state. A change in the gate threshold value makes it impossible to operate the MOSFET as intended, thus posing a problem. Therefore, the present specification provides a switching circuit that is capable of, while preventing the change in the gate threshold value, allowing the MOSFET formed in the SiC semiconductor layer to be switched.

A switching circuit disclosed herein comprises a main MOSFET, a control MOSFET, and a diode. The main MOSFET is formed in a SiC semiconductor layer. A channel type of the main MOSFET is a first conductivity type. A channel type of the control MOSFET is a second conductivity type. A source of the control MOSFET is connected to a gate of the main MOSFET. A cathode of the diode is connected to a gate of one of the main MOSFET and the control MOSFET. An anode of the diode is connected to a gate of the other of the main MOSFET and the control MOSFET. A channel type of the one is an n-type. A channel type of the other is a p-type.

It should be noted that one of the first conductivity type and the second conductivity type is an n-type and the other of the first conductivity type and the second conductivity type is a p-type.

This switching circuit allows the main MOSFET to be switched by a potential of the gate of the control MOSFET. In the following, the potential of the gate of the control MOSFET is referred to as “signal potential”.

First, a case where the channel type of the main MOSFET is the n-type is described. In order for the gate of the main MOSFET to be charged, the signal potential (i.e. the potential of the anode of the diode) is raised. The control MOSFET is thereby turned off and the diode is turned on, as a result of which the gate of the main MOSFET is charged. This causes the main MOSFET to be turned on. In order for the gate of the main MOSFET to be discharged, the signal potential is lowered. A reverse voltage is thereby applied to the diode, thus bringing the diode into an off state. Further, lowering of the signal potential causes the potential of the gate of the control MOSFET to be lowered, thus causing the control MOSFET to be turned on. Charges are released from the gate of the main MOSFET via the control MOSFET. This causes the main MOSFET to be turned off. In this way, the switching circuit allows the main MOSFET to be switched. Further, in a case where the signal potential is extremely lowered by a surge or the like, a reverse voltage is applied to the diode, thus bringing the diode into an off state. It is possible to prevent the low signal potential from being applied to the gate of the main MOSFET. The change in the gate threshold value of the main MOSFET is thereby prevented.

Alternatively, in a case where the channel type of the main MOSFET is the p-type, the switching circuit operates in basically the same manner as it does in the case where the channel type of the main MOSFET is the n-type, albeit with a difference in direction of currents. In the case where the channel type of the main MOSFET is the p-type, the application of an extremely high potential to the gate of the main MOSFET is prevented. This prevents the change in the gate threshold value of the main MOSFET.

### BRIEF DESCRIPTION OF DRAWINGS

FIG. 1 is a circuit diagram of a switching circuit 10.

FIG. 2 is a graph showing the characteristics of MOSFETs 12 and 14.

FIG. 3 is a top view of a semiconductor chip 70.

FIG. 4 is a longitudinal sectional view of the semiconductor chip 70 in an area in which the control MOSFET 14 is formed.

FIG. 5 is a longitudinal sectional view of the semiconductor chip 70 in an area in which a diode 16 is formed (i.e. a longitudinal sectional view taken along a line V-V of FIG. 6).

FIG. 6 is a diagram showing an arrangement of an anode region 81 and a cathode region 82 as viewed from above the semiconductor chip 70.

FIG. 7 is a graph explaining how the switching circuit 10 operates.

FIG. 8 is a circuit diagram of a switching circuit 210.

FIG. 9 is a graph explaining how the switching circuit 210 operates.

### DESCRIPTION OF EMBODIMENTS

### First Embodiment

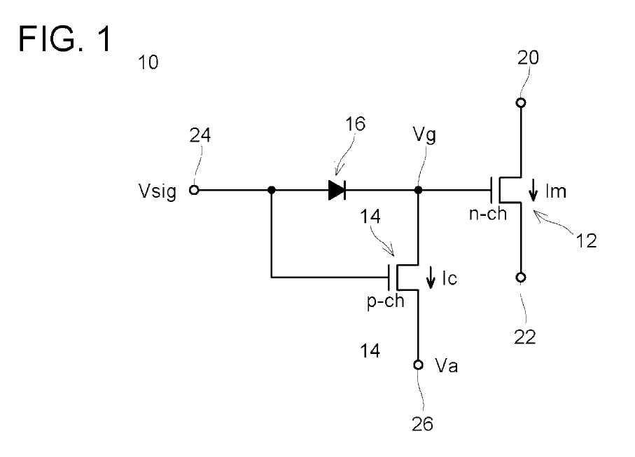

FIG. 1 shows a switching circuit 10 of the first embodiment. The switching circuit 10 includes a main MOSFET 12, a control MOSFET 14, and a diode 16.

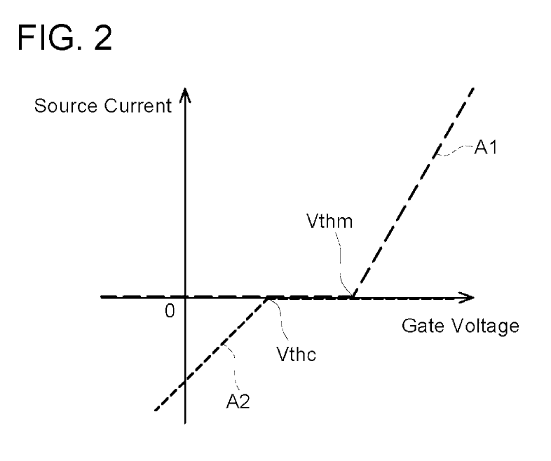

The main MOSFET 12 is a MOSFET of an n-channel type. A drain of the main MOSFET 12 is connected to a high-potential wire 20, and a source of the main MOSFET 12 is connected to a low-potential wire 22. The main MOSFET 12 is a MOSFET formed in a SiC substrate. More particularly, the main MOSFET 12 includes an n-type source region, a p-type body region, and an n-type drain region, all of which are formed in the SiC substrate. Further, a gate insulator film (silicon oxide film) is in contact with the body region. A gate electrode faces the body region via the gate insulator film. The application of a potential that is equal to or higher than a threshold value to the gate electrode forms an n-type channel in the body region, so that the source region and the drain region are connected to each other through the channel. The main MOSFET 12 is turned on as a result. A line Al of the graph of FIG. 2 shows characteristics of the main MOSFET 12. As shown in FIG. 2, the main MOSFET 12 has a positive gate threshold value Vthm. The main MOSFET 12 is turned on when a potential that is equal to or higher than the threshold value Vthm is applied to a gate of the main MOSFET 12.

The control MOSFET 14 is a MOSFET of a p-channel type. A source of the control MOSFET 14 is connected to the gate of the main MOSFET 12. A drain of the control MOSFET 14 is connected to a negative wire 26. A gate of the control MOSFET 14 is connected to a signal wire 24. The control MOSFET 14 is a MOSFET formed in a polysilicon semiconductor layer. More particularly, the control MOSFET 14 includes a p-type source region, an n-type body region, and a p-type drain region, all of which are formed in the polysilicon semiconductor layer (note, however, that the body region may be of the p type). Further, a gate insulator film (silicon oxide film) is in contact with the body region. A gate electrode faces the body region via the gate insulator film. The application of a potential that is equal to or lower than the threshold value to the gate electrode forms a p-type channel in the body region, so that the source region and the drain region are connected to each other through the channel. This causes the control MOSFET 14 to be turned on. A line A2 of the graph of FIG. 2 shows the characteristics of the control MOSFET 14. As shown in FIG. 2, the control MOSFET 14 has a positive gate threshold value Vthc. The control MOSFET 14 is turned on when a potential that is equal to or lower than the threshold value Vthc is applied to the gate of the control MOSFET 14.

The diode 16 is a pn diode. A cathode of the diode 16 is connected to the gate of the main MOSFET 12 and the source of the control MOSFET 14. An anode of the diode 16 is connected to the gate of the control MOSFET 14 and the signal wire 24.

A potential Vsig for controlling the main MOSFET 12 is inputted to the signal wire 24. A potential Va is applied to the negative wire 26. The potential Va is a zero or negative potential, and is a potential that is lower than the gate threshold value Vthm of the main MOSFET 12.

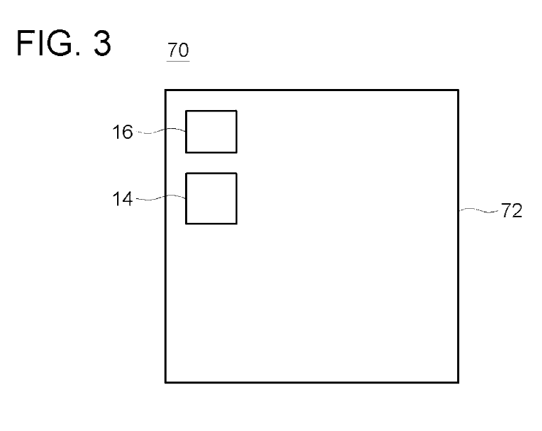

The main MOSFET 12, the control MOSFET 14, and the diode 16 are formed in a single semiconductor chip 70 shown in FIG. 3. The semiconductor chip 70 includes a SiC substrate 72. Although not illustrated, the main MOSFET 12 is formed in the SiC substrate 72.

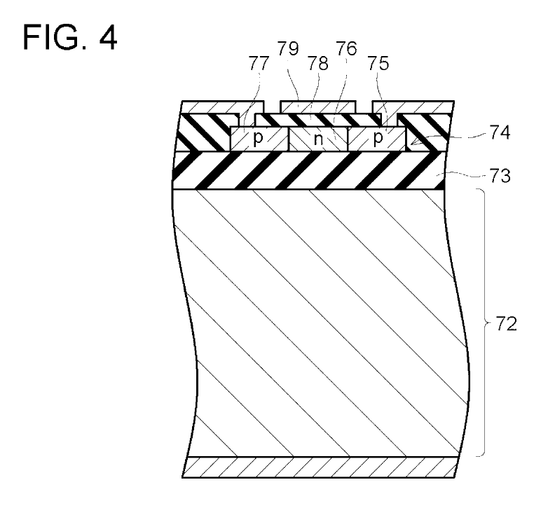

As shown in FIGS. 3 and 4, the control MOSFET 14 is formed on a surface of the SiC substrate 72. That is, as shown in FIG. 4, an interlayer insulator film 73 is formed on the surface of the SiC substrate 72. A polysilicon layer 74 is formed on a surface of the interlayer insulator film 73. A p-type source region 75, an n-type body region 76, and a p-type drain region 77 are formed in the polysilicon layer 74 (Note, however, that the body region 76 may be of the p type.). A gate insulator film 78 and a gate electrode 79 are formed on a surface of the body region 76. The control MOSFET 14 is formed by the source region 75, the body region 76, the drain region 77, the gate electrode 79, and the like. The control MOSFET 14 is connected as shown in FIG. 1 by wires formed on the surface of the SiC substrate 72.

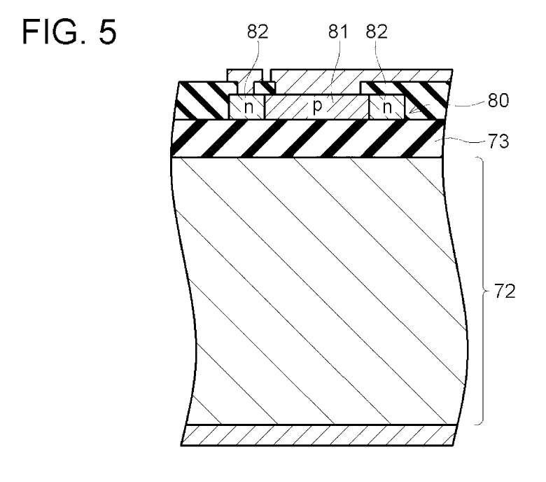

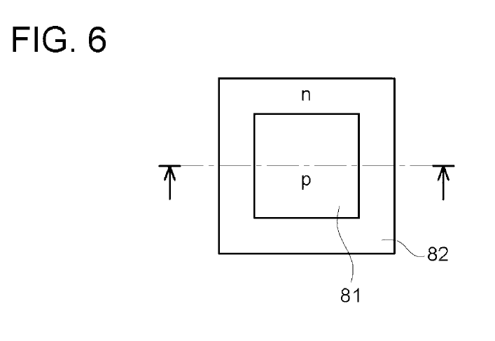

As shown in FIGS. 3 and 5, the diode 16 is formed on the surface of the SiC substrate 72. That is, as shown in FIG. 5, a polysilicon layer 80 is formed on the surface of the interlayer insulator film 73. A p-type anode region 81 and an n-type cathode region 82 are formed in the polysilicon layer 80. As shown in FIG. 6, the cathode region 82 is formed in such a manner as to surround the anode region 81. The diode 16 is formed by the anode region 81 and the cathode region 82. The diode 16 is connected as shown in FIG. 1 by wires formed on the surface of the SiC substrate 72.

The following will describe how the switching circuit 10 operates. In a state where the main MOSFET 12 is off, the potential Vsig of the signal wire 24 is controlled to be a low potential VL. The potential VL is a zero or negative potential, and is substantially equal to the potential Va. The potential VL is applied to the gate of the control MOSFET 14. The potential VL is lower than the gate threshold value Vthc of the control MOSFET 14. For this reason, the control MOSFET 14 is on, and the potential Va is applied to the gate of the main MOSFET 12. That is, the gate potential Vg is substantially equal to the potential Va. Since the potential Va is lower than the gate threshold value Vthm of the main MOSFET 12, the main MOSFET 12 is off.

In order for the main MOSFET 12 to be turned on, the potential Vsig of the signal wire 24 is raised from the low potential VL to a high potential VH. The potential VH is a positive potential. The potential VH is a potential that is higher than the gate threshold value Vthc of the control MOSFET 14 and is also a potential that is higher than the gate threshold value Vthm of the main MOSFET 12. When the potential Vsig is controlled to be the high potential VH, the potential VH is applied to the gate of the control MOSFET 14. The control MOSFET 14 is thereby turned off. Further, since the potential Vsig (=VH) is higher than the gate potential Vg, the diode 16 is turned on. For this reason, a current flows from the signal wire 24 toward the gate of the main MOSFET 12, thus causing charges to be fed to the gate of the main MOSFET 12. The gate potential Vg of the main MOSFET 12 is raised to a potential that is substantially equal to the potential VH. More particularly, the gate potential Vg rises to a potential that is obtained by subtracting a forward voltage drop VF of the diode 16 from the potential VH. Since the potential VH−VF is higher than the gate threshold value Vthm of the main MOSFET 12, the main MOSFET 12 is turned on.

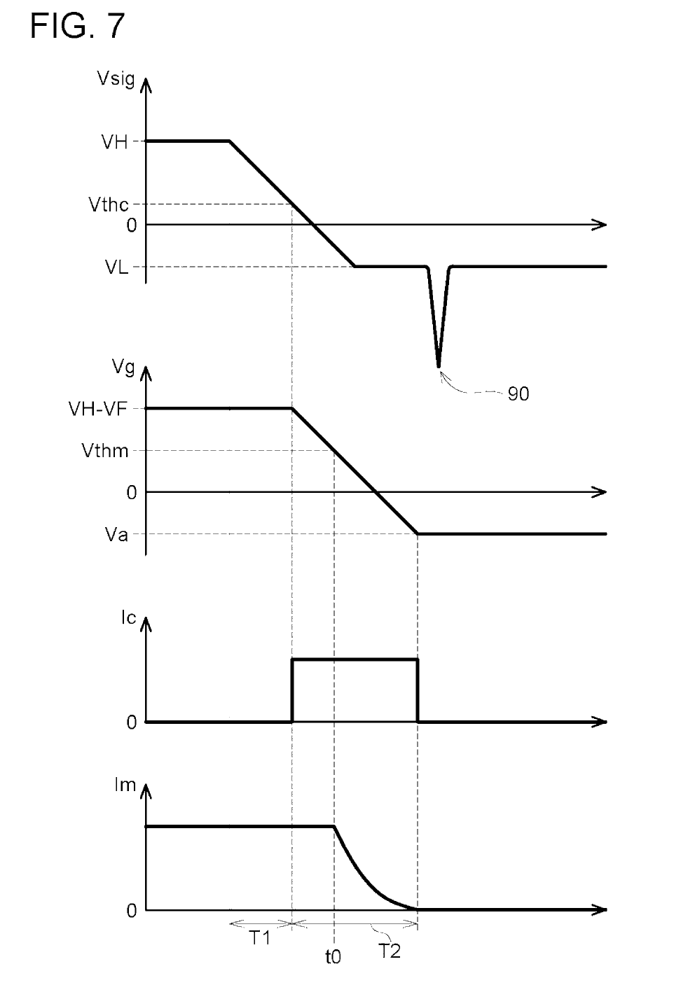

In order for the main MOSFET 12 to be turned off, the potential Vsig of the signal wire 24 is lowered from the high potential VH to the low potential VL as shown in FIG. 7. The following describes a process of operation of lowering the potential Vsig from the high potential VH to the low potential VL. When the potential Vsig starts to be lowered from the potential VH, the potential Vsig of the signal wire 24 becomes lower than the gate potential Vg (=VH−VF). The diode 16 is thereby turned off. Further, at a stage where the potential Vsig starts to be lowered, the potential Vsig of the signal wire 24 (i.e. the gate potential of the control MOSFET 14) is higher than the gate threshold value Vthc of the control MOSFET 14. The control MOSFET 14 is thereby maintained in an off state. That is, the control MOSFET 14 is off during a period T1 shown in FIG. 7. Therefore, during the period T1, no charge is released from the gate of the main MOSFET 12, and the gate potential Vg is kept at the potential VH−VF. After that, when the potential Vsig of the signal wire 24 becomes lower than the gate threshold value Vthc of the control MOSFET 14, the control MOSFET 14 is turned on. For this reason, a current Ic flows through the control MOSFET 14 during a period T2 that follows the period T1. The charges are thereby released from the gate of the main MOSFET 12. Therefore, during the period T2, the gate potential Vg of the main MOSFET 12 is lowered. The gate potential Vg is lowered to a potential that is substantially equal to the potential Va. At a timing t0 in the period T2, the gate potential Vg falls below the gate threshold value Vthm of the main MOSFET 12. Then, a current Im flowing through the main MOSFET 12 is lowered to substantially zero. That is, the main MOSFET 12 is turned off.

As described above, the switching circuit 10 allows the main MOSFET 12 to be switched by controlling the potential Vsig.

Further, for example, there is a case where a negative surge 90 shown in FIG. 7 is superposed on the potential Vsig. In the switching circuit 10, even if the surge 90 causes the potential Vsig to be an extremely low negative potential, the application of the reverse voltage to the diode 16 brings the diode 16 into the off state. This makes it possible to prevent the negative surge 90 from being applied to the gate of the main MOSFET 12. This makes it possible to prevent the change in the gate threshold value of the main MOSFET 12 formed in the SiC substrate. Further, the surge 90 is applied to the gate of the control MOSFET 14. However, the control MOSFET 14 is of the p-channel type and is formed in the silicon semiconductor layer. For this reason, even if an extremely low potential is applied to the gate of the control MOSFET 14, there is hardly any change in gate threshold value of the control MOSFET 14. Therefore, in the switching circuit 10, even if the negative surge is superposed on the potential Vsig, there is hardly any change in the characteristics of the circuit 10. Therefore, the switching circuit 10 allows the main MOSFET 12 to be stably switched.

### Second Embodiment

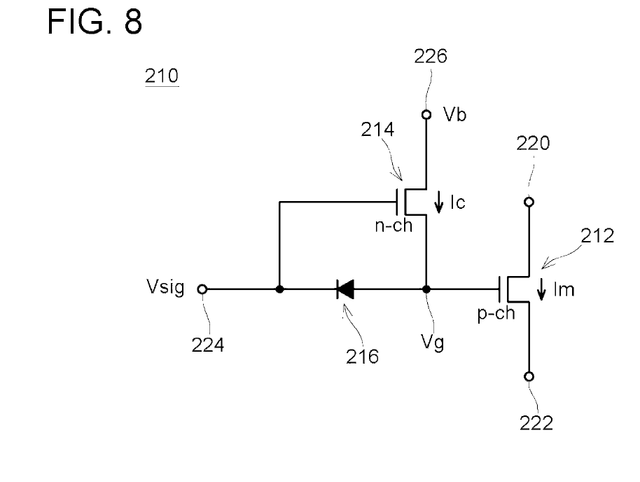

FIG. 8 shows a switching circuit 210 of the second embodiment. The switching circuit 210 includes a main MOSFET 212 of the p-channel type and a control MOSFET 214 of the n-channel type. A configuration of the switching circuit 210 of the second embodiment will be described in detail below.

The main MOSFET 212 is a MOSFET of the p-channel type. A source of the main MOSFET 212 is connected to a high-potential wire 220, and a drain of the main MOSFET 212 is connected to a low-potential wire 222. The main MOSFET 212 is a MOSFET formed in a SiC substrate. The main MOSFET 212 is turned on when a potential that is equal to or lower than a threshold value Vthm is applied to a gate of the main MOSFET 212.

The control MOSFET 214 is a MOSFET of the n-channel type. A source of the control MOSFET 214 is connected to the gate of the main MOSFET 212. A drain of the control MOSFET 214 is connected to a positive wire 226. A gate of the control MOSFET 214 is connected to a signal wire 224. The control MOSFET 214 is a MOSFET formed in a polysilicon semiconductor layer. The control MOSFET 214 is turned on when a potential that is equal to or higher than a threshold value Vthc is applied to the gate of the control MOSFET 214.

A diode 216 is a pn diode. An anode of the diode 216 is connected to the gate of the main MOSFET 212 and the source of the control MOSFET 214. A cathode of the diode 216 is connected to the gate of the control MOSFET 214 and the signal wire 224.

A potential Vsig for controlling the main MOSFET 212 is inputted to the signal wire 224. A potential Vb is applied to the positive wire 226. The potential Vb is a positive potential, and is a potential that is higher than the gate threshold value Vthm of the main MOSFET 212.

The following will describe how the switching circuit 210 operates. In a state where the main MOSFET 212 is off, the potential Vsig of the signal wire 224 is controlled to be a high potential VH. The potential VH is a positive potential, and is substantially equal to the potential Vb. The potential VH is applied to the gate of the control MOSFET 214. The potential VH is higher than the gate threshold value Vthc of the control MOSFET 214. For this reason, the control MOSFET 214 is on, and the potential Vb is applied to the gate of the main MOSFET 212. That is, the gate potential Vg is substantially equal to the potential Vb. Since the potential Vb is higher than the gate threshold value Vthm of the main MOSFET 212, the main MOSFET 212 is off.

In order for the main MOSFET 212 to be turned on, the potential Vsig of the signal wire 224 is lowered from the high potential VH to a low potential VL. The potential VL is a negative potential. The potential VL is a potential that is lower than the gate threshold value Vthc of the control MOSFET 214 and is also a potential that is lower than the gate threshold value Vthm of the main MOSFET 212. When the potential Vsig is controlled to be the low potential VL, the potential VL is applied to the gate of the control MOSFET 214. The control MOSFET 214 is thereby turned off. Further, since the potential Vsig (=VL) is lower than the gate potential Vg, the diode 216 is turned on. For this reason, a current flows from the gate of the main MOSFET 212 toward the signal wire 224, and thus releasing charges from the gate of the main MOSFET 212. The gate potential Vg of the main MOSFET 212 is thereby lowered to a potential that is substantially equal to the potential VL. More particularly, the gate potential Vg is lowered to a potential that is obtained by adding a forward voltage drop VF of the diode 216 to the potential VL. Since the potential VL+VF is lower than the gate threshold value Vthm of the main MOSFET 212, the main MOSFET 212 is turned on.

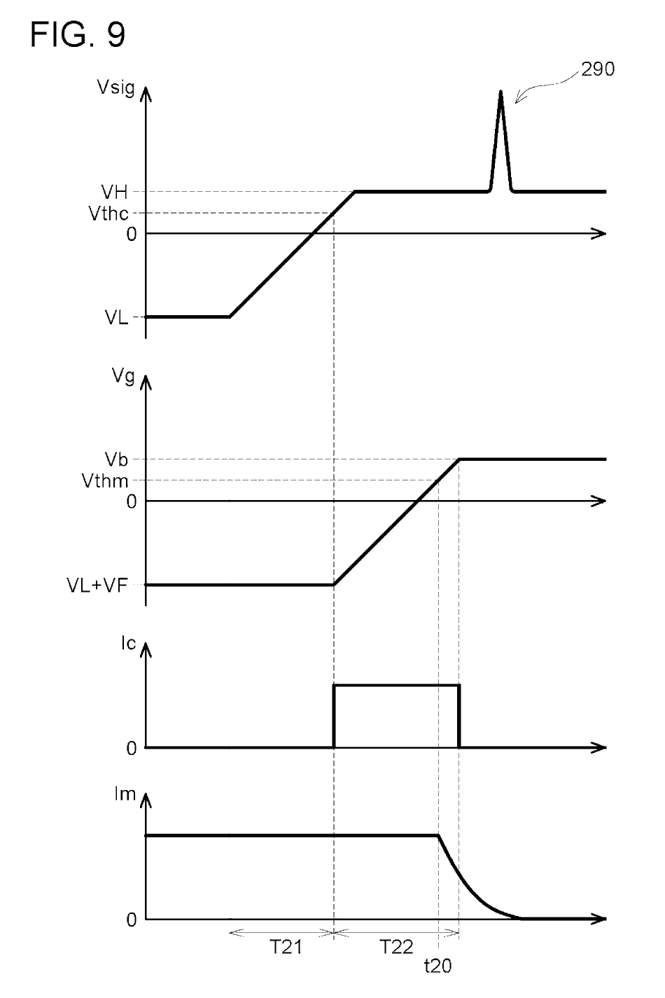

In order for the main MOSFET 212 to be turned off, the potential Vsig of the signal wire 224 is raised from the low potential VL to the high potential VH as shown in FIG. 9. The following will describe a process of operation of raising the potential Vsig from the low potential VL to the high potential VH. When the potential Vsig starts to be raised from the potential VL, the potential Vsig of the signal wire 224 becomes higher than the gate potential Vg (=VL+VF). The diode 216 is thereby turned off. Further, at the stage where the potential Vsig starts to be raised, the potential Vsig of the signal wire 224 (i.e. the gate potential of the control MOSFET 214) is lower than the gate threshold value Vthc of the control MOSFET 214. The control MOSFET 214 is thereby maintained in an off state. That is, the control MOSFET 214 is off during a period T21 shown in FIG. 9. Therefore, during the period T21, no charge is supplied to the gate of the main MOSFET 212, and the gate potential Vg is kept at the potential VL+VF. After that, when the potential Vsig of the signal wire 224 becomes higher than the gate threshold value Vthc of the control MOSFET 214, the control MOSFET 214 is turned on. For this reason, a current Ic flows through the control MOSFET 214 during a period T22 that follows the period T21. Charges are thereby supplied to the gate of the main MOSFET 212. Therefore, during the period T22, the gate potential Vg of the main MOSFET 212 rises. The gate potential Vg rises to a potential that is substantially equal to the potential Vb. At a timing t20 in the period T22, the gate potential Vg exceeds the gate threshold value Vthm of the main MOSFET 212. Then, a current Im flowing through the main MOSFET 212 is lowered to substantially zero. That is, the main MOSFET 212 is turned off.

As described above, the switching circuit 210 allows the main MOSFET 212 to be switched by controlling the potential Vsig.

Further, for example, there is a case where a positive surge 290 shown in FIG. 9 is superposed on the potential Vsig. In the switching circuit 210, even if the surge 290 raises the potential Vsig to be an extremely high positive potential, the application of a reverse voltage to the diode 216 brings the diode 216 into an off state. This makes it possible to prevent the positive surge 290 from being applied to the gate of the main MOSFET 212. This makes it possible to prevent a change in the gate threshold value of the main MOSFET 212 formed in the SiC substrate. Further, the surge 290 is applied to the gate of the control MOSFET 214. However, the control MOSFET 214 is of the n-channel type and is formed in the polysilicon semiconductor layer. For this reason, even if an extremely high potential is applied to the gate of the control MOSFET 214, there is hardly any change in gate threshold value of the control MOSFET 214. Therefore, in the switching circuit 210, even if the positive surge is superposed on the potential Vsig, there is hardly any change in the characteristics of the circuit 210. This allows the main MOSFET 212 to be stably switched.

In the first and second embodiments described above, the diodes 16 and 216 are pn diodes. The diodes 16 and 216 may alternatively be other types of diodes such as Schottky barrier diodes.

Further, in the first and second embodiments described above, the MOSFETs 14 and 212 of the p-channel type have positive threshold values. The MOSFETs 14 and 212 may alternatively have negative threshold values.

The MOSFET described herein may be configured as below. The control MOSFET may be formed in the silicon semiconductor layer. This configuration makes it possible to prevent a change in the gate threshold value of the control MOSFET.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

1. A switching circuit, comprising:
a main MOSFET formed in a SiC semiconductor layer, a channel type of the main MOSFET being a first conductivity type;
a control MOSFET, a channel type of which is a second conductivity type and a source of which is connected to a gate of the main MOSFET; and
a diode, a cathode of which is connected to a gate of one of the main MOSFET and the control MOSFET, and an anode of which is connected to a gate of the other of the main MOSFET and the control MOSFET, a channel type of the one being an n-type, and a channel type of the other being a p-type.

2. The switching circuit of claim 1, wherein the control MOSFET is formed in a silicon semiconductor layer.
